(19) United States
(12) Patent Application Publication
(10) Pub. No.: US 2012/0098142 A1
(43) Pub. Date: Apr. 26, 2012

(54) ELECTRICAL CONTACT FOR A DEEP BURIED LAYER IN A SEMI-CONDUCTOR DEVICE

(75) Inventors: Giuseppe Croce, Missaglia (LC) (IT); Fabrizio Fausto Renzo Toia, Busto Arsizio (VA) (IT); Alessandro Dundulachi, Vimercate (MB) (IT)

(73) Assignee: STMICROELECTRONICS S.R.L., Agrate Brianza (MB) (IT)

(21) Appl. No.: 13/239,633

(22) Filed: Sep. 22, 2011

(30) Foreign Application Priority Data
Oct. 26, 2010 (IT) VI2010A000287

(51) Int. Cl. H01L 23/522; H01L 21/768

(52) U.S. Cl. 257/774; 438/643; 257/E23.145; 257/E21.578

(57) ABSTRACT

A semi-conductor device includes at least one deep buried layer with an electrical connection made thereto by an electrical contact. The electrical contact to the deep buried layer is made by formed an opening through the use of a first chemical attack and a second chemical attack after the first chemical attack. By making an opening, the electrical contact can be made with the deep buried layer without at the same time occupying excessively wide portions of the device. For example, it is possible to make electrical contacts having a width of less than 1.5 μm with deep layers having a depth of more than 5 μm.

### PRIORITY CLAIM

This application claims priority from Italian Application for Patent No. VI 2010A000287 filed Oct. 26, 2010, the disclosure of which is hereby incorporated by reference.

### TECHNICAL FIELD

The present invention concerns the field of semi-conductor technology. In particular, the present invention concerns a semi-conductor device comprising at least one deep buried layer connected by means of an electrical contact to the surface of the device and a method for making said contact.

### BACKGROUND

In the field of semi-conductor devices, deep buried layers made in the semi-conductor substrate are often used. For example, in the case of bipolar CMOS, heavily doped deep buried layers are used so as to improve the properties of the system. Indeed, the deep buried layer provides a low-resistance contact that extends beneath the bipolar device. In this way, for example, it is possible to decrease the resistance of the collector of the device so as to ensure high response speeds and low power consumption.

One of the main problems connected with the presence of deep buried layers concerns making the electrical contacts with said deep layers.

Generally, the electrical contact with the deep buried layers is made by making so-called “sinkers”. A sinker is manufactured by implanting high-energy ions into the surface of the substrate and then diffusing, for example through high-temperature annealing, such ions in the substrate for long enough so that they reach the deep buried layer to make the electrical contact with.

This method does, however, have a series of problems and drawbacks. In particular, the depths that can be reached through this method are generally limited to no more than 4 μm since greater depths would require excessively long annealing times. In particular, long annealing involves a substantial increase in the costs of the process for manufacturing the device. Moreover, long annealing involves the diffusion of the implanted ions not only in the vertical direction, i.e. depthwise in the substrate, but also in other directions, in particular sideways. This means that contact regions are made that extend very far laterally and thus occupy excessively large areas of the semi-conductor substrate, thus reducing the level of miniaturization of the system.

A further problem relative to the formation of sinkers to make the electrical contact with deep layers in a semi-conductor substrate concerns the resistance of the contact. When, indeed, it is necessary to reach great depths, for example of the order of about 4 μm, the electrical resistance of the sinkers is generally too high.

Consequently, it would be helpful to provide a method for forming an electrical contact with a deep buried layer in a semi-conductor device capable of overcoming these problems.

### SUMMARY

The present disclosure concerns a semi-conductor device comprising at least one deep buried layer connected by means of an electrical contact to the surface of the device and a method for making said contact. The present disclosure is based on the idea of making the contact with the deep buried layer by using a first chemical attack and a second chemical attack after the first chemical attack. In this way, electrical contacts with very deep buried layers can be made without at the same time occupying excessively large portions of the device

According to a first embodiment, a method for forming an electrical contact with a deep buried layer in a semi-conductor device comprising a dielectric pre-metal layer and a semi-conductor substrate inside which is said deep buried layer is thus provided, said method comprising the following steps:

a) carrying out a first chemical attack to make a first contact cavity in the dielectric pre-metal layer at the deep buried layer, said first contact cavity having a depth corresponding at least to the thickness of the dielectric pre-metal layer;

b) carrying out a second chemical attack to make a contact trench in the semi-conductor layer, said contact trench communicating with said first contact cavity and having a depth corresponding at least to the depth of said deep buried layer with respect to the surface of said semi-conductor layer;

c) filling the first contact cavity and the contact trench with a conductive material.

In this way, the electrical contact with the deep buried layer is made in an easy and inexpensive manner through the first contact cavity and the contact trench. In other words, the first contact cavity and the contact trench can directly communicate with one another since, for example, they are arranged one on top of the other along the vertical direction. Based on this method, the deep buried layer can be arranged at any depth inside the semi-conductor substrate, even at depths of over 5 μm.

According to a further embodiment, a method is provided in which the semi-conductor device also comprises a region of insulating oxide arranged between the dielectric pre-metal layer and the semi-conductor substrate, in which the first chemical attack allows a second contact cavity to also be formed in the region of insulating oxide, said second contact cavity communicating with said first contact cavity and having a depth corresponding at least to the thickness of said region of insulating oxide and in which the filling step c) allows the second contact cavity to also be filled with the conductive material.

In this way, even when there is a further region of insulating oxide in the system, the contact with the deep buried layer can easily be made through the first contact cavity, the second contact cavity and the contact trench. In other words, the second contact cavity allows the first contact cavity to be placed in communication with the contact trench. The first contact cavity, the second contact cavity and the contact trench can, for example, be placed directly on top of one another in this order from the top downwards along the vertical direction.

The region of insulating oxide allows the properties of the electrical contact with the deep buried layer to be improved, given that it provides optimal insulation between the electrical contact with the deep buried layer and the other devices possibly present in the surrounding regions of the semi-conductor substrate. In other words, the region of insulating oxide in this way surrounds the electrical contact with the deep buried layer and makes it possible to improve its insulation with the other devices possibly present in the surrounding regions of the semi-conductor substrate.

According to a further embodiment, a method is provided also comprising the following step:

b2) forming a protective layer on the side walls of the contact trench, the protective layer being suitable for inhibiting the conductive material from coming out from the contact trench, said step b2) being carried out before said step c).

In this way, the conductive material is inhibited from coming out. In particular, the protective layer is formed so as to be arranged between the conductive material of the electrical contact with the deep buried layer and the semi-conductive material of the surrounding substrate. This makes it possible to avoid direct contact between the conductive material and the semi-conductive material of the surrounding substrate and thus to inhibit the diffusion of the conductive material in the semi-conductive material. The protective layer can comprise, for example, an oxide layer.

According to a further embodiment, a method is provided also comprising the following step:

c1) depositing a layer of conductive material on the walls of the contact cavities and of the contact trench, in which said step c1) is carried out before said step c).

In this way a protective layer of the side walls of the contact cavities and of the contact trench can be created that is able to inhibit the formation of defects. Moreover, the conductive material can be selected so as to optimize the resistance of the contact. This makes it possible to increase the properties of the electrical contact with the deep buried layer. The layer of conductive material can comprise a liner layer, for example a layer of Ti. The layer of conductive material can also comprise a barrier layer, for example a layer of TiN.

According to a further embodiment, a method is provided also comprising the following steps:

i) manufacturing at least one side contact cavity in said dielectric pre-metal layer, said side contact cavity not communicating with the first contact cavity, in which said step i) is carried out before said steps a) and b).

In this way, not only is the contact with the deep buried layer manufactured, but also the contact with at least one or more of the active components manufactured in the semi-conductor substrate. In other words, the method according to this embodiment makes it possible to easily and inexpensively make the various electrical connections of the device integrating the steps of the manufacturing process.

According to a further embodiment, a method is provided in which the step a) also comprises the following sub-step:

a1) depositing a resist material on the dielectric pre-metal layer so as to create a mask for manufacturing said first contact cavity and said contact trench and in such a way that said resist material at least partially fills said side contact cavity. In this way, the side contact cavity not yet filled with conductive material is protected during the subsequent manufacturing steps of the electrical contact with the deep buried layer.

According to a further embodiment, a method is provided in which the step c1) makes it possible to deposit the layer of conductive material also on the walls of the side contact cavity.

In this way, the depositing of the layer of conductive material in the various cavities is carried out in an integrated manner and at the same time for all of the conductive regions to be manufactured.

According to a further embodiment, a method is provided in which said step c) makes it possible to also fill said side contact cavity through the conductive material.

In this way the filling of the various cavities with conductive material is carried out in an integrated manner and at the same time for all the conductive regions to manufacture.

According to a further embodiment, a method is provided in which the depth of the deep buried layer with respect to the surface of the semi-conductor substrate is equal to at least 5 μm.

According to a further embodiment, a method is provided in which the width of the electrical contact measured at the level of the upper surface of the dielectric pre-metal layer is equal to 1.5 μm or less.

According to a further embodiment, a method is provided in which the aspect ratio of the electrical contact with the deep buried layer, i.e. the ratio between the depth of the contact and its width, is equal to at least 2 or more. In particular, based on further embodiments of the present invention, the aspect ratio can be between 2 and 6. Moreover, based on a particularly advantageous embodiment of the present invention, the aspect ratio can be equal to 5. This value of the aspect ratio allows the electrical contact to be filled with conductive material for example by means of PVD (Physical Vapor Deposition) and/or CVD (Chemical Vapor Deposition) techniques.

According to a further embodiment, a semi-conductor device is provided, comprising a semi-conductor substrate, a deep buried layer inside the semi-conductor substrate, a dielectric pre-metal layer, and an electrical contact with said deep buried layer, characterized in that: said electrical contact can be obtained with one of the methods.

According to a further embodiment, a semi-conductor device is provided in which the depth of the deep buried layer with respect to the surface of the semi-conductor substrate is equal to at least 5 μm.

According to a further embodiment, a semi-conductor device is provided in which the width of the electrical contact measured at the level of the upper surface of the dielectric pre-metal layer is equal to 1.5 μm or less.

According to a further embodiment, a semi-conductor device is provided in which the aspect ratio of the electrical contact with the deep buried layer, i.e. the ratio between the depth of the contact and its width, is equal to at least 2 or more. In particular, based on further embodiments, the aspect ratio can be between 2 and 6. Moreover, based on a particularly advantageous embodiment, the aspect ratio can be equal to 5.

### BRIEF DESCRIPTION OF THE DRAWINGS

FIG. 1 schematically shows a first step of the method for manufacturing a contact for a deep buried layer in a semi-conductor device;

FIG. 2 schematically shows a second step of the method for manufacturing a contact for a deep buried layer in a semi-conductor device;

FIG. 3 schematically shows a third step of the method for manufacturing a contact for a deep buried layer in a semi-conductor device;

FIG. 4 schematically shows a fourth step of the method for manufacturing a contact for a deep buried layer in a semi-conductor device;

FIG. 5 schematically shows a fifth step of the method for manufacturing a contact for a deep buried layer in a semi-conductor device;

FIG. 6 schematically shows a sixth step of the method for manufacturing a contact for a deep buried layer in a semi-conductor device;

FIG. 7 schematically shows a seventh step of the method for manufacturing a contact for a deep buried layer in a semi-conductor device;

FIG. 8 schematically shows an eighth step of the method for manufacturing a contact for a deep buried layer in a semi-conductor device;

FIG. 9 schematically shows a ninth step of the method for manufacturing a contact for a deep buried layer in a semi-conductor device;

FIG. 10 schematically shows a tenth step of the method for manufacturing a contact for a deep buried layer in a semi-conductor device;

FIG. 11 schematically shows an eleventh step of the method for manufacturing a contact for a deep buried layer in a semi-conductor device; and

FIG. 12 schematically shows a step of the method for manufacturing a contact for a deep buried layer in a semi-conductor device.

### DETAILED DESCRIPTION OF THE DRAWINGS

Hereafter, embodiments are described with reference to the attached figures. However, the invention is not limited to the particular embodiments described in the following detailed description and shown in the figures, but rather, the described embodiments simply give examples of different aspects of the present invention the scope of which is defined by the claims.

Further modifications and variations of the present invention will be clear to the man skilled in the art. Consequently, the present description must be considered as comprising all of said modifications and/or variations of the present invention the scope of which is defined by the claims.

Corresponding elements are indicated for the sake of simplicity in the figures with similar reference numerals.

Moreover, hereafter, unless specified otherwise, the horizontal direction is the direction of the main surface of the semi-conductor device. Consequently, the vertical direction is the direction perpendicular to the surface of the semi-conductor device. Moreover, unless specified otherwise, the term “width” indicates the sizes parallel to the horizontal direction and the terms “height”, “depth” and “thickness” indicate sizes parallel to the vertical direction.

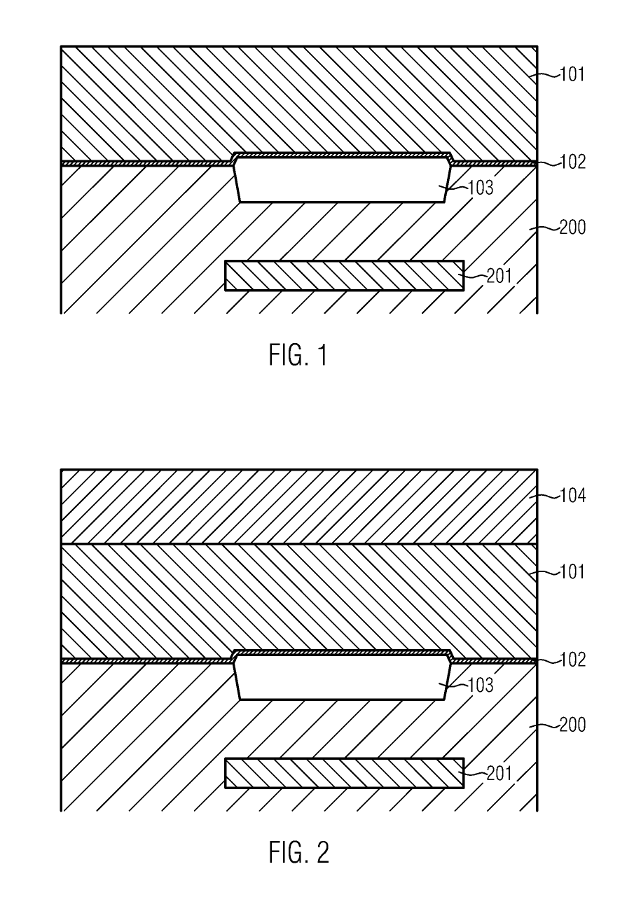

FIG. 1 schematically shows a first step of the method for manufacturing a contact for a deep buried layer 201 in a semi-conductor device.

The system comprises a semi-conductor substrate 200, for example a layer of silicon and a region of insulating oxide 103. The region of insulating oxide 103 can for example be a region of field oxide. The region of insulating oxide 103 can for example have a thickness of 0.2 μm-0.6 μm. Preferably, the region of insulating oxide 103 can have a thickness of about 0.4 μm.

The system also comprises a deep buried layer 201 arranged beneath the region of insulating oxide 103. The deep buried layer 201 can for example correspond to an area of the semi-conductor substrate 200 that is heavily doped, for example with Arsenic and/or Antimony. The deep buried layer 201 can be at various depths with respect to the surface of the semi-conductor substrate 200. For example, the deep buried layer 201 can be at a depth of at least 3 μm with respect to the surface of the semi-conductor substrate 200. Moreover, based on the present invention, the deep buried layer can be arranged at great depths like for example at depths of 4 μm or more, of 5 μm or more, of 6 μm or more. The system shown in FIG. 1 also comprises a layer of borderless nitride 102 arranged in direct contact with the surface of the substrate 200 and of the region of insulating oxide 103. Nevertheless, the presence of the layer 102 is optional. In general, the layer 102 can have a thickness for example of the order of 150-350 Angstroms.

The system also comprises a dielectric pre-metal layer 101 (PMD layer), i.e. a layer of dielectric material that separates the semi-conductor substrate 200 and the devices made in the substrate itself from the first layer of metal made on the system, to create the electrical connections between the various devices. The dielectric pre-metal layer 101 can for example comprise oxide. The dielectric pre-metal layer can have various thicknesses, for example thicknesses of between 0.5 μm and 1 μm. In the system shown schematically in FIG. 1, the layer of borderless nitride is arranged between the semi-conductor substrate 200 and the dielectric pre-metal layer 101.

Given that the techniques for manufacturing the structures shown schematically in FIG. 1 are known in literature, they are not described in detail within the present description.

FIG. 2 schematically shows a second step of the method for manufacturing a contact for a deep buried layer 201 in a semi-conductor device according to an embodiment of the present invention. In particular, in the step shown in FIG. 2, a mask 104 is deposited on the layer of pre-metal dielectric 101. The mask 104 can for example be formed from resist GKR.

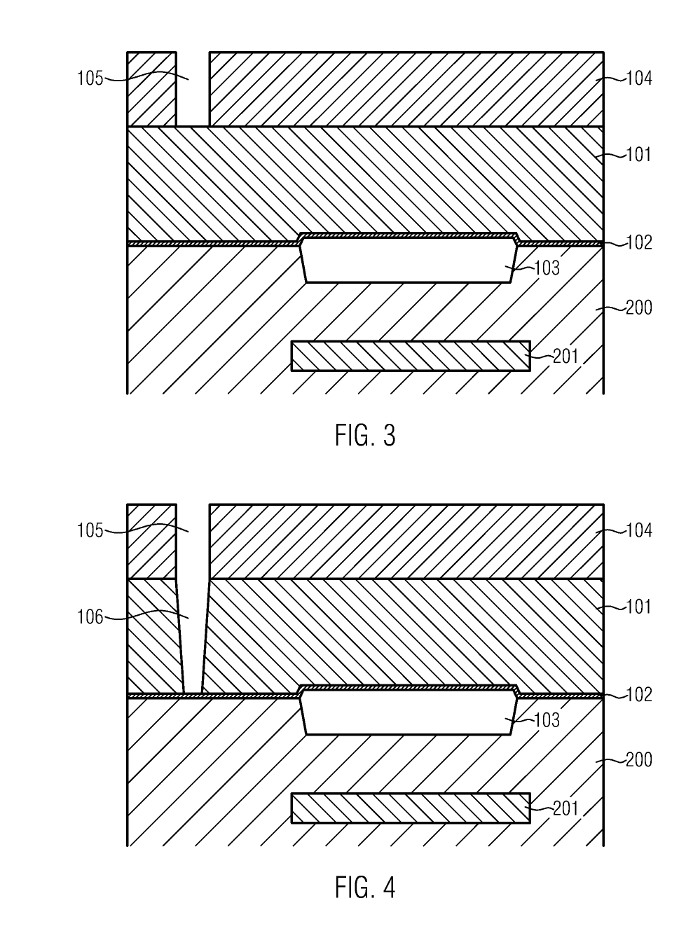

The mask 104 is deposited to make the contact pathways of the interconnection structures of the system as described in relation to FIGS. 3, 4 and 5.

In particular, through photolithography techniques it is possible to select the position and the dimensions of the contact pathways to be manufactured in the system. For example, as shown in FIG. 3, the mask 104 is structured through photolithography so as to create the structure 105. At this point, the side cavity 106 is bored inside the pre-metal dielectric material 101 through chemical attack (FIG. 4).

It should be noted that, for the sake of simplicity, a single side cavity 106 for making contact pathways in the system has been shown to have been made. In reality, there can be various contact pathways based on the structure of the device to be manufactured. In particular, as known in the state of the art, the contact pathways are made inside the dielectric pre-metal layer to create the suitable electrical connections between the various devices made in the semi-conductor substrate and also to create the electrical contacts between the devices made in the semi-conductor substrate and other devices for example in the architecture of a complex electronic system.

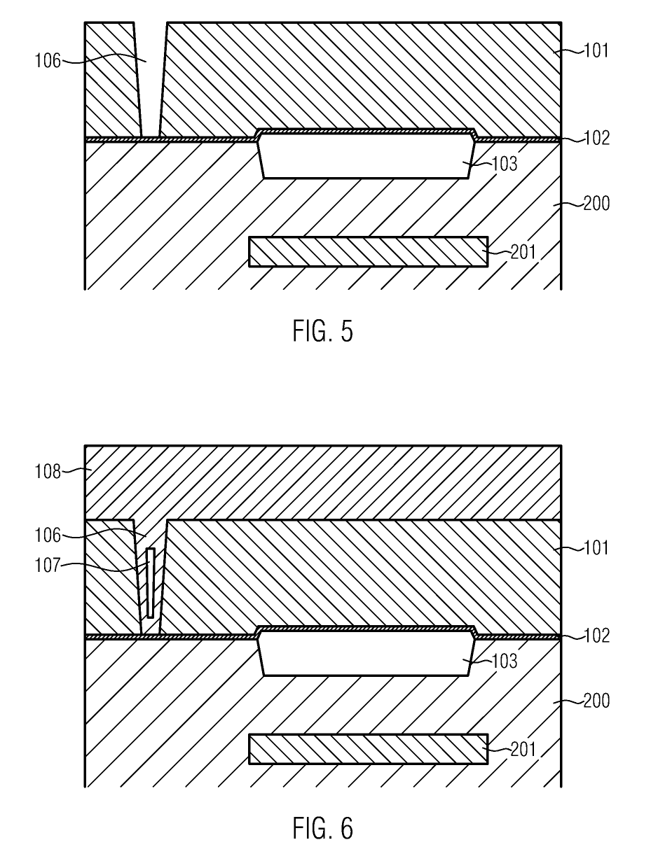

As shown in FIG. 5, the mask 104 is removed. In particular, the mask 104 can be removed by dry and/or wet removal.

Based on the present invention, the side cavities 106 are not filled with conductive material at this point of the step of manufacturing the system. In particular, at this point of the manufacturing step of the system based on the present invention, the contact with the deep buried layer 201 is manufactured.

The contact with the deep buried layer 201 is not manufactured at the same time as the manufacturing of the side cavities 106 since, as described in detail hereafter, the manufacturing of the contact with the deep buried layer 201 requires dedicated process steps. However, the filling of the contact with the deep buried layer 201 through conductive material can be carried out at the same time as the filling of the side cavities 106 so as to integrate the manufacturing steps of the device.

Firstly, as shown in FIG. 6, a layer of resist material 108 (for example resist GKR) is deposited on the system. As shown in the figures, the resist material 108 does not only grow above the layer of pre-metal dielectric material 101 forming the mask, but also fills the side cavities like the cavity 106 made in the previous steps and not filled with conductive material. In this way, the side cavities made in the previous steps are protected and thus remain unaltered in the subsequent steps of the process for manufacturing the contact with the deep buried layer 201. FIG. 6 also shows that inside the side cavity 106 a hollow region 107 is formed. This is due to the spin coating method with which the resist layer 108 can be deposited on the system. The presence of the hollow region 107 does not however influence the subsequent steps of the method according to the present invention.

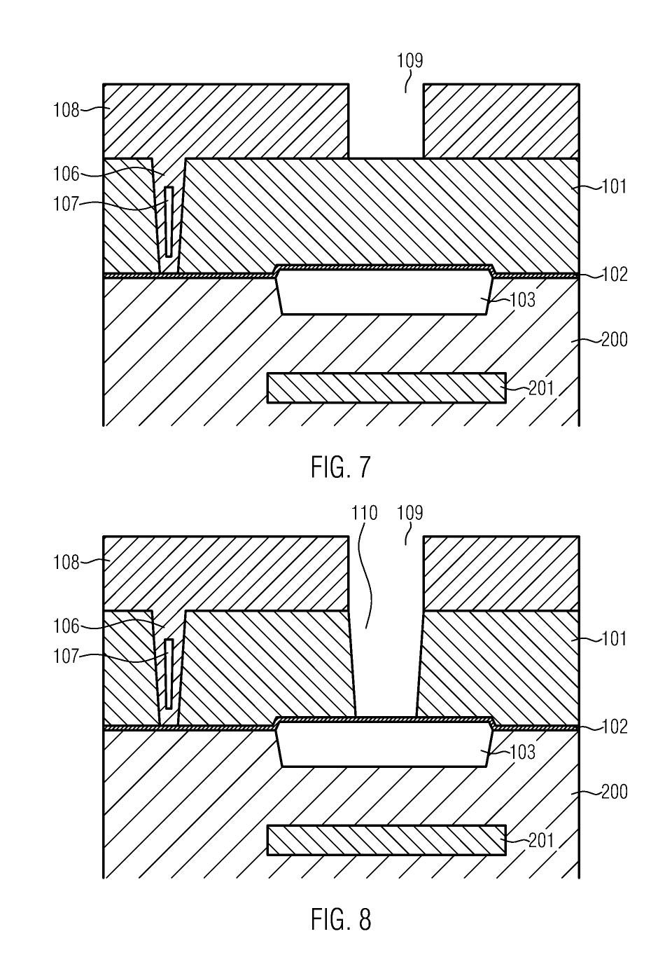

As shown in FIG. 7, the resist layer 108 is structured through known photolithography techniques so as to identify the regions in which to create the contact with the deep buried layer 201 made in the semi-conductor substrate 200. In particular, FIG. 7 shows the creation of the structure 109 in the resist layer 108. The structure 109 is made at the layer of field oxide 103. The dimensions of the structure 109 influence the dimensions of the contact structure that it is wished to manufacture with the deep buried layer 201. The desired dimensions of this contact structure depend on the type of applications of the system to be made, but in general it has a width of about 1.0-1.5 μm. For these reasons, the structure 109 can also be made with a width of about 1.0-1.5 μm.

Moreover, according to particular embodiments of the present invention, the width of the structure 109 can be selected so that the aspect ratio of the contact structure with the deep buried layer, i.e. the ratio between the depth of the contact structure and its width, is equal to at least 2 or more. In particular, based on further embodiments of the present invention, the aspect ratio can be between 2 and 6. Moreover, based on a particularly advantageous embodiment of the present invention, the aspect ratio can be equal to 5.

In the next step, the cavity 110 is created in the dielectric pre-metal layer 101 (FIG. 8). The cavity 110 is made through a first chemical attack, for example through chemical attack based on fluorine/oxygen. As shown in the figures, the walls of the cavity 110 are oblique. This is due to the type of chemical attack that is used to make the cavity itself and in any case it does not influence the subsequent steps of the method according to the present invention and the functionality of the contact structure to be made.

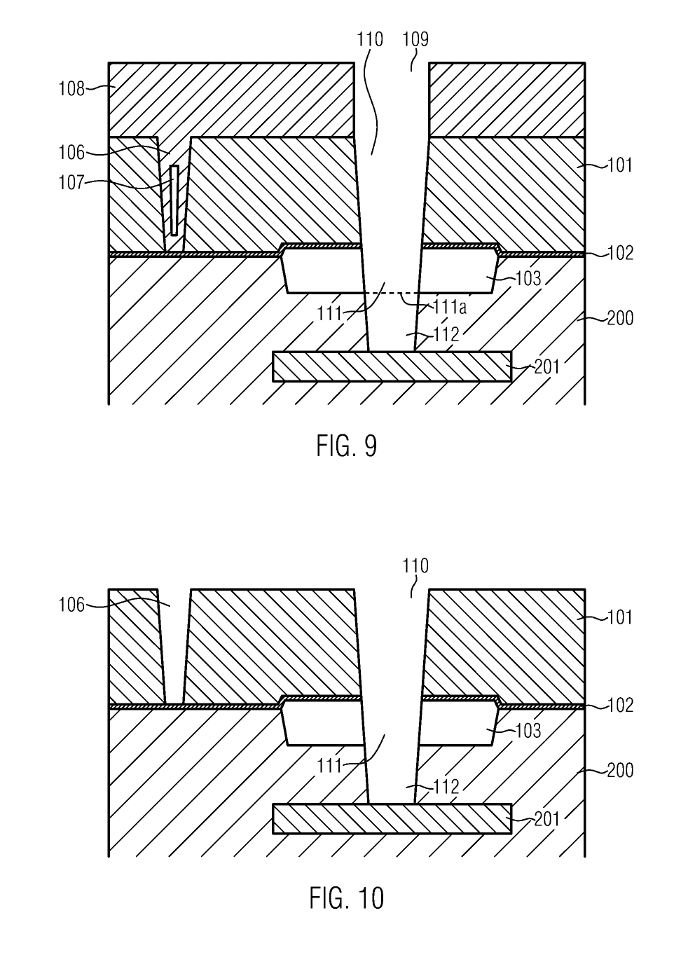

Moreover, in the embodiment of the present invention schematically shown in the figures, the first chemical attack used to make the cavity 110 in the dielectric pre-metal layer 101 allows the cavity 111 to be made inside the region of field oxide 103 (FIG. 9). Moreover, as shown in FIG. 9, through the first chemical attack the portion of borderless nitride layer 102 arranged between the cavity 110 and the cavity 111 is removed.

The base materials of fluorine and oxygen used for the first chemical attack carried out to make the cavities 110 and 111 in the dielectric pre-metal layer 101 and in the region of field oxide 103, respectively, are such that the first chemical attack stops selectively in contact with the semi-conductive material of the substrate 200 (broken line 111a in FIG. 9).

As shown further in FIG. 9, after having made the cavities 110 and 111 in the dielectric materials 101 and 103 through the first chemical attack process, a second chemical attack is carried out so as to make a trench 112 inside the semi-conductive material 200 and beneath the cavity 111. This chemical attack can be carried out for example through materials based on sulphur hexafluoride (SF₆) and on octafluorocyclobutane (C₄F₈).

The depth of the trench 112 is such that the deep buried layer 201 is reached. In particular, the depth of the trench 112 in the semi-conductive material 200 (measured, in the case of the system shown in FIG. 9, from the lower surface of the region 103, i.e. from the broken line indicated with reference numeral 111a) can be about 4-5 μm or even more.

Moreover, the depth of the trench 112 can also be such that the trench 112 itself partially or totally penetrates into the thickness of the deep buried layer 201. In the case in which the trench 112 penetrates into the thickness of the deep buried layer 201, the resistance of the contact with the deep buried layer 201 can be kept at low levels.

The materials used for the second chemical attack carried out to make the trench 112 in the semi-conductor substrate 200 are such that the second chemical attack does not alter the cavities made through the first chemical attack.

After having made the trench 112, the resist material 108 is removed through dry and/or wet removal (FIG. 10). In particular, in this way, not only is the layer of material 108 arranged above the dielectric pre-metal layer 101 removed, but also the dielectric material 108 that fills the side cavities 106 made previously to form the various electrical contacts of the system.

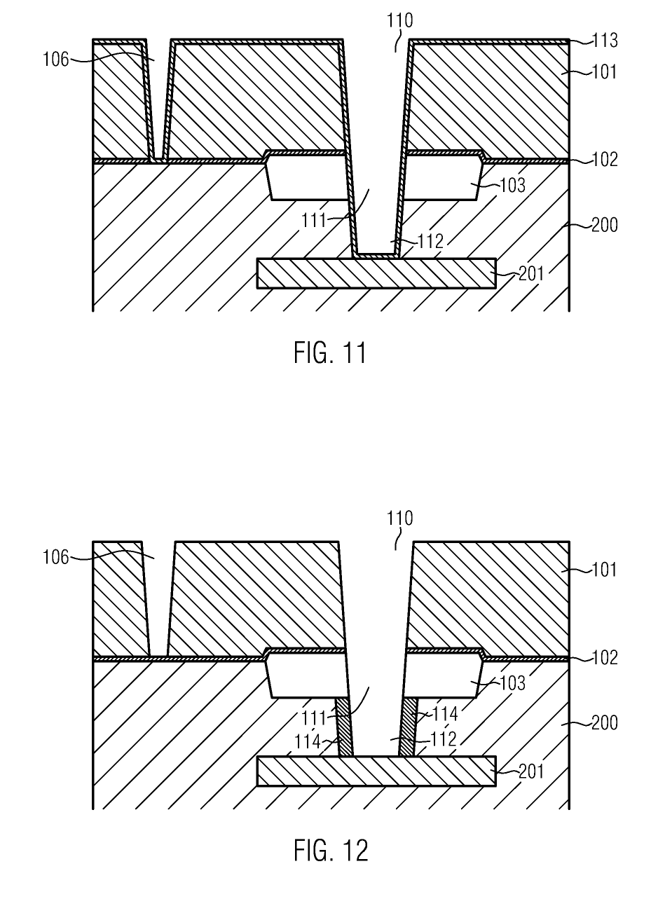

In the subsequent step (FIG. 11) a layer of conductive material 113 is deposited. In particular, the layer of conductive material 113 coats the side walls and the bottom of the cavities present in the system. The depositing of conductive material 113, indeed, makes it possible to coat both the walls of the side cavity 106 and the walls of the cavity formed by the cavities 110 and 111 and by the trench 112 to make the contact with the deep buried layer 201. Preferably, the material 113 comprises Ti, which allows the value of the resistance of the contact to be reduced. Moreover, a further layer of TiN can also be deposited to protect the layer of Ti and to inhibit the formation of defects at the interface between the layer of Ti and the conductive material that is used to fill the cavities.

After having formed the layer 113, the manufacturing of the contact with the deep buried layer 201 is considered by depositing conductive material inside the cavities. For example, tungsten (W) can be deposited. Also in this case, the conductive material fills both the pathways 106 and the cavity made to form the contact with the deep buried layer 201.

Finally, polishing techniques like CMP (chemical mechanical polishing) can be carried out to flatten the upper surfaces of the conductive material.

The method described as an example with respect to FIGS. 1 to 11 thus makes it possible to simultaneously complete both the contact with a deep buried layer and the contacts with the devices made in the semi-conductor substrate. This is particularly advantageous because it makes it possible to combine steps of the process for manufacturing the semi-conductor system and thus to reduce the time and consequently the costs. In particular, the steps of the process relative to the filling of the various cavities through conductive material can be combined.

FIG. 12 schematically shows a further aspect of the present invention based on a particular embodiment thereof. In particular, FIG. 12 shows the formation of a protective layer 114 on the side walls of the contact trench 112. The protective layer 114 is suitable for inhibiting the conductive material from coming out from the contact trench 112. In particular, the protective layer 114 is suitable for inhibiting the diffusion of the conductive material that is located inside the contact trench 112 through the side walls of the trench itself. In particular, in the absence of the protective layer 114, the conductive material that occupies the trench 112 can diffuse from the trench 112 to the semi-conductive material of the surrounding substrate 200. In other words, the presence of the protective layer 114 on the side walls of the contact trench 112 makes it possible to avoid direct contact between the conductive material that is located inside the trench and the semi-conductive material of the surrounding substrate.

The presence of the protective layer 114 on the side walls of the contact trench 112 can for example be particularly advantageous in the case in which the trench 112 is made near to devices that work at high voltage. The presence of the protective layer 114 on the side walls of the contact trench 112 can also be advantageous for example in the case in which the trench 112 is made at heavily doped areas of the semi-conductor substrate.

The protective layer 114 can have a thickness within the range from 100 Angstroms to 300 Angstroms.

The protective layer 114 can for example be an oxide layer.

The protective layer 114 can be formed after having formed the contact trench 112 as described with reference to FIG. 9.

In particular, after having formed the contact trench 112 through the second chemical attack as described above, it is possible to carry out an RTO (Rapid Thermal Oxidation) process, for example through the ISSG (In Situ Steam Generation) technique so as to be able to accurately control the growth of the protective layer 114 on the side walls of the contact trench 112. In particular, due to the morphology of the system, the RTO and above all the ISSG technique, are preferable with respect to other dry or wet oxidation techniques since they allow the protective layer 114 to be made accurately and precisely.

For example, through RTO or ISSG techniques it is possible to make a layer of protective oxide having a thickness within the range from 100 Angstroms to 300 Angstroms on the walls of the contact trench 112.

The oxidation process involves the formation of oxide not only on the side walls of the contact trench 112 but also on the bottom of said trench. This is due to the fact that during the oxidation process the portion of material of the deep buried layer 201 that, after the second chemical attack, is at the bottom of the contact trench 112 is also oxidized. For this reason, before filling the contact trench 112 of conductive material, it is necessary to carry out an attack process on the oxide to ensure that the bottom of the contact trench 112 is open towards the material of the deep buried layer 201 so as to be able to make the electrical contact with it. In particular, as schematically shown in FIG. 12, after having carried out the attack process on the oxide, there is no layer of oxide on the bottom of the contact trench 112. The bottom of the contact trench 112 is formed from the material of the deep buried layer 201 so that the conductive material that fills the contact trench 112 is in electrical contact with the deep buried layer 201.

In order to remove the oxide formed on the bottom of the insulation trench 112 it is possible to use a blanket attack process, i.e.

an attack process without masks. During the blanket attack process, a thin upper layer of the dielectric pre-metal layer 101 is used as sacrificial layer. In other words, an upper portion of the dielectric pre-metal layer 101 is consumed during the blanket attack process.

After having formed the protective layer 114 on the side walls of the contact trench 112, the contact is completed, for example as described above with reference to FIG. 11. For example, the layer of conductive material 113 can be formed before proceeding with the filling of the contact trench 112 with conductive material. In this way, the conductive material that is inside the contact trench 112 is in contact with the layer of conductive material 113 that, in turn, is in contact with the protective layer 114. In other words, the conductive material that is inside the contact trench 112 is separated from the semi-conductive material of the surrounding substrate 200 through, in order, the layer of conductive material 113 and the protective layer 114. Alternatively, the contact trench 112 can be filled with conductive material without having formed the layer of conductive material 113. In this case, the conductive material that is inside the contact trench 112 is separated from the semi-conductive material of the surrounding substrate 200 through the protective layer 114.

Although the present invention has been described with reference to the embodiments described above, it is clear for the man skilled in the art that it is possible to make various modifications, variations and improvements of the present invention in light of the teaching described above and within the scope of the attached claims without departing from the object and from the scope of protection of the invention.

For example, although the method for simultaneously making a contact with a deep buried layer and a side contact pathway 106 has been shown, the method according to the present invention can also foresee making just the contact with a deep buried layer. Moreover, the method according to the present invention can also foresee to make any number of contacts with as many deep layers. As well as this, the number of contacts with deep layers and of side contact pathways in the pre-metal dielectric material that can be advantageously made through the present invention is not limited to any particular value. In particular, it is possible to simultaneously make any number of contacts with as many deep layers and any number of electrical contact pathways in the pre-metal dielectric material to connect together the devices created in the semi-conductive material or to make the electrical contacts with other devices within the architecture of a complex electronic system.

Moreover, the position and size of the contacts with the deep layers are set through known techniques, for example using suitably structured masks and the method according to the present invention does not foresee restrictions with respect to these parameters. Moreover, even if based on the method described as an example with reference to FIGS. 1 to 12 the contact with the deep buried layer 201 is made through the dielectric pre-metal layer 101, the layer of borderless nitride 102, the region of insulating oxide 103 and the semi-conductor substrate 200 within which is the deep buried layer 201, based on the method according to the present invention other configurations are possible. For example, the contact with the deep buried layer can be made through a dielectric pre-metal layer and the semi-conductor substrate inside which is the deep buried layer to be connected, for example in regions of the device in which there is no layer of borderless nitride, nor the regions of insulating oxide or for devices where these elements are not foreseen at all. Moreover, the contact with the deep buried layer can be made through a dielectric pre-metal layer, a layer of insulating oxide and the semi-conductor substrate inside which is the deep buried layer to be connected, for example in regions of the device in which there is no layer of borderless nitride, or for devices where the layer of borderless nitride is not foreseen at all.

As well as this, aspects that are considered known to the man skilled in the art have not been described so as to avoid needlessly overshadowing the described invention.

Consequently, the invention is not limited to the embodiments described above, but it is just limited by the scope of protection of the attached claims.

What is claimed is:

1. A method for forming an electrical contact with a deep buried layer in a semi-conductor device comprising a dielectric pre-metal layer and a semi-conductor substrate inside which is said deep buried layer, comprising:
a) carrying out a first chemical attack to make a first contact cavity in said dielectric pre-metal layer towards said deep buried layer, said first contact cavity having a depth corresponding at least to the thickness of said dielectric pre-metal layer;
b) carrying out a second chemical attack to make a contact trench in said semi-conductor layer, said contact trench communicating with said first contact cavity and having a depth corresponding at least to the depth of said deep buried layer with respect to the surface of said semi-conductor layer;
c) filling said first contact cavity and said contact trench with a conductive material.

2. The method according to claim 1, wherein said semi-conductor device also comprises a region of insulating oxide arranged between said dielectric pre-metal layer and said semi-conductor substrate, wherein carrying out said first chemical attack further forms a second contact cavity in said region of insulating oxide, said second contact cavity communicating with said first contact cavity and having a depth corresponding at least to the thickness of said region of insulating oxide; and
wherein said step c) also fills said second contact cavity with said conductive material.

3. The method according to claim 1, further comprising:
b2) forming a protective layer on the side walls of said contact trench, said protective layer being suitable for inhibiting said conductive material from coming out from said contact trench, said step b2) being carried out before said step c).

4. The method according to claim 1, further comprising:
c1) depositing a layer of conductive material on the walls of said contact cavities and of said contact trench; wherein said step c1) is carried out before said step c).

5. The method according to claim 1, further comprising:
i) manufacturing at least one side contact cavity in said dielectric pre-metal layer, said side contact cavity not communicating with said first contact cavity, wherein said step i) is carried out before said steps a) and b).

6. The method according to claim 5, wherein said step a) comprises:
a1) depositing a resist material on said dielectric pre-metal layer so as to create a mask for manufacturing said first contact cavity and said contact trench and so that said resist material at least partially fills said side contact cavity.

7. The method according to claim 5 further comprising:
c1) depositing a layer of conductive material on the walls of said contact cavities and of said contact trench; wherein said step c1) is carried out before said step c); and
wherein said step c1) allows said layer of conductive material to also be deposited on the walls of said side contact cavity.

8. The method according to claim 5 wherein said step c) further fills said side contact cavity with said conductive material.

9. The method according to claim 1, wherein an aspect ratio of said electrical contact with said deep buried layer is equal to at least 2 or greater.

10. The method according to claim 1, wherein an aspect ratio of said electrical contact with said deep buried layer is equal to at least 5.

11. A semi-conductor device, comprising:
a semi-conductor substrate,
a deep buried layer inside said semi-conductor substrate,
a dielectric pre-metal layer, and an electrical contact with said deep buried layer, wherein said electrical contact is formed by an opening made through dielectric pre-metal layer and a portion of the semi-conductor substrate to reach the dielectric pre-metal layer, said opening being filled with a conductive metal material.

12. The device according to claim 11, wherein a depth of said deep buried layer with respect to a surface of said semi-conductor substrate is equal to at least 5 μm.

13. The device according to claim 11, wherein a width of said electrical contact measured at a level of an upper surface of said dielectric pre-metal layer is equal to 1.5 μm or less.

14. The device according to claim 11, wherein an aspect ratio of said electrical contact is equal to at least 2 or greater.

15. The device according to claim 11, wherein an aspect ratio of said electrical contact is equal to at least 5.

16. A method comprising:
forming a deep buried layer within a semi-conductor substrate;
forming a dielectric pre-metal layer over the semi-conductor substrate;
etching an opening extending through the dielectric pre-metal layer and extending into the semi-conductor substrate until reaching the deep buried layer; and
filling said opening with a conductive metal material.

17. The method of claim 16 wherein etching the opening comprises:
performing a first etch to form a first cavity in said dielectric pre-metal layer, said first contact cavity having a depth corresponding at least to the thickness of said dielectric pre-metal layer; and
performing a second etch through the first cavity to form a second cavity, said second cavity being in communicating with said first cavity and having a depth corresponding at least to the depth of said deep buried layer with respect to the surface of said semi-conductor layer.

18. The method of claim 16 further comprising:
forming an insulating region between the semi-conductor substrate and the dielectric pre-metal layer, the insulating region being positioned above the deep buried layer; and
wherein etching the opening comprises etching the opening so as to extend through both the dielectric pre-metal layer and the insulating region and further extending into the semi-conductor substrate until reaching the deep buried layer.

19. The method of claim 16, further comprising:
forming a protective layer on side walls of said opening, said protective layer being located on side walls of the semi-conductor substrate formed by said opening.

20. The method of claim 16 further comprising:
etching an additional opening extending through the dielectric pre-metal layer to contact an upper surface of the semi-conductor substrate; and
wherein filling said opening with a conductive metal material comprises filling in a single filling operation both said opening and said additional opening with the conductive metal material.
